(19) United States
(12) Patent Application Publication
(10) Pub. No.: US 2025/0285892 A1
(43) Pub. Date: Sep. 11, 2025

(54) Semiconductor Manufacturing Apparatus, Pushup Method, and Method for Manufacturing Semiconductor Device

(71) Applicant: Fasford Technology Co., Ltd., Minami-Alps City (JP)

(72) Inventors: Yuki NAKUI, Minami-Alps (JP); Tsuyoshi YOKOMORI, Minami-Alps (JP); Tatsuyuki OKUBO, Minami-Alps (JP); Hiroshi MAKI, Minami-Alps (JP); Akira SAITO, Minami-Alps (JP); Naoki OKAMOTO, Minami-Alps (JP)

(21) Appl. No.: 19/049,140

(22) Filed: Feb. 10, 2025

(30) Foreign Application Priority Data
Mar. 11, 2024 (JP) 2024-037609

(51) Int. Cl. H01L 21/67; H01L 21/683

(52) U.S. Cl. CPC H01L 21/67276; H01L 21/67132; H01L 21/67144; H01L 21/6836; H01L 2221/68327; H01L 2221/68386

(57) ABSTRACT

The present disclosure aims to provide a technology that makes it easy to create a time chart recipe. Disclosed is a semiconductor manufacturing apparatus including a pushup unit, a display device, and a control unit. The pushup unit has a plurality of blocks that are each able to independently move up and down. The display device displays a setting screen that configures a pushup sequence for the plurality of blocks with a plurality of steps and allows the height of the plurality of blocks to be inputted for each step. The control unit is configured to be able to set a plurality of pushup parameters by inputting one of setting items displayed on the setting screen and control the operations of the plurality of blocks in accordance with the setting plurality of pushup parameters.

### CLAIM OF PRIORITY

The present application claims priority from Japanese patent application JP 2024-037609 filed on Mar. 11, 2024, the content of which is hereby incorporated by reference into this application.

### BACKGROUND OF THE INVENTION

The present disclosure relates to a semiconductor manufacturing apparatus, and is applicable, for example, to a die bonder having a pushup unit.

One step in a semiconductor device manufacturing process is a peeling step in which a die separated from a wafer is peeled off from a dicing tape. In the peeling step, for example, the pushup unit peels off the dies one by one from the rear surface of the dicing tape held by a wafer supply unit, and then the dies are picked up using a collet or other suction nozzle provided, for example, on a pickup head or a bond head.

The pushup unit is configured such that, for example, each of a plurality of blocks is able to operate independently. A pushup sequence for the plurality of blocks is formulated by a plurality of steps, and operations of the plurality of blocks of the pushup unit are controlled based on a time chart recipe that allows the height and velocity of the plurality of blocks to be set for each block and each step. (For example, Japanese Unexamined Patent Application Publication No. 2020-161534).

### SUMMARY OF THE INVENTION

The time chart recipe disclosed in Japanese Unexamined Patent Application

Publication No. 2020-161534 is complicated, difficult to create, and time-consuming.

An object of the present disclosure is to provide a technology that makes it easy to create the time chart recipe. Other objects and novel features will be apparent from the description of this document and the accompanying drawings.

A brief summary of representative aspects of the present disclosure is given below. In short, according to an aspect of the present disclosure, there is provided a semiconductor manufacturing apparatus including a pushup unit, a display device, and a control unit. The pushup unit has a plurality of blocks that are each able to independently move up and down. The display device displays a setting screen that configures a pushup sequence for the plurality of blocks with a plurality of steps and allows the height of the plurality of blocks to be inputted for each step. The control unit is configured to be able to set a plurality of pushup parameters by inputting one of setting items displayed on the setting screen and control the operations of the plurality of blocks in accordance with the setting plurality of pushup parameters.

The present disclosure makes it possible, for example, to facilitate the creation of the time chart recipe.

### BRIEF DESCRIPTION OF THE DRAWINGS

FIG. 1 is a schematic top view illustrating an example of the configuration of a die bonder according to an embodiment.

FIG. 2 is a diagram illustrating a schematic configuration as viewed in the direction of arrow A in FIG. 1.

FIG. 3 is a schematic cross-sectional view illustrating essential parts of a wafer supply unit depicted in FIG. 1.

FIG. 4 is a block diagram illustrating a schematic configuration of a control system of the die bonder depicted in FIG. 1.

FIG. 5 is a flowchart illustrating a method for manufacturing semiconductor device by using the die bonder depicted in FIG. 1.

FIG. 6 is a top view of a pushup unit depicted in FIG. 2.

FIG. 7 is a schematic cross-sectional view of essential parts of the pushup unit depicted in FIG. 6.

FIG. 8 is a schematic diagram illustrating an example where blocks and drive shafts are connected in a case where the number of blocks is smaller than four.

FIG. 9 is a diagram illustrating the flow of setting the time chart recipe from a setting screen.

FIG. 10 is a diagram illustrating an example of settings in the setting screen for a multi-stage operation in a four-stage block and the height of the blocks based on the settings.

FIG. 11 is a diagram illustrating the timing of block operations performed in a pushup sequence based on the settings in the setting screen depicted in FIG. 10.

FIG. 12 is a diagram illustrating an example of settings in the setting screen for a reverse multi-stage operation and the height of the blocks based on the settings.

FIG. 13 is a diagram illustrating the timing of block operations performed in a pushup sequence based on the settings in the setting screen depicted in FIG. 12.

FIG. 14 is a diagram illustrating an example of settings in the setting screen for the reverse multi-stage operation in a three-stage block and the height of the blocks based on the settings.

FIG. 15 is a diagram illustrating an example of settings in the setting screen for the reverse multi-stage operation in a two-stage block and the height of the blocks based on the settings.

FIG. 16 is a diagram illustrating another example of settings in the setting screen for the reverse multi-stage operation in the four-stage block and the height of the blocks based on the settings.

FIG. 17 is a diagram illustrating an example of settings in the setting screen for a general-purpose operation in the four-stage block and the height of the blocks based on the settings.

FIG. 18 is a diagram illustrating another example of settings in the setting screen for the reverse multi-stage operation in the four-stage block and the height of the blocks based on the settings.

FIG. 19 is a diagram illustrating the timing of block operations performed in a pushup sequence based on the settings in the setting screen depicted in FIG. 18.

### DETAILED DESCRIPTION OF THE PREFERRED EMBODIMENTS

An embodiment will be described below with reference to the drawings. It should be noted that in the following description, the same components are indicated by the same reference numerals, and the repeated description thereof may be omitted. It should be noted that to make the description more clearly, the drawings may be schematically represented for the widths, thicknesses, shapes, and the like of the respective portions as compared with the actual form. In addition, also between a plurality of mutual drawings, the dimension relationships between the respective elements, the ratios between the respective elements, and the like do not always coincide with each other.

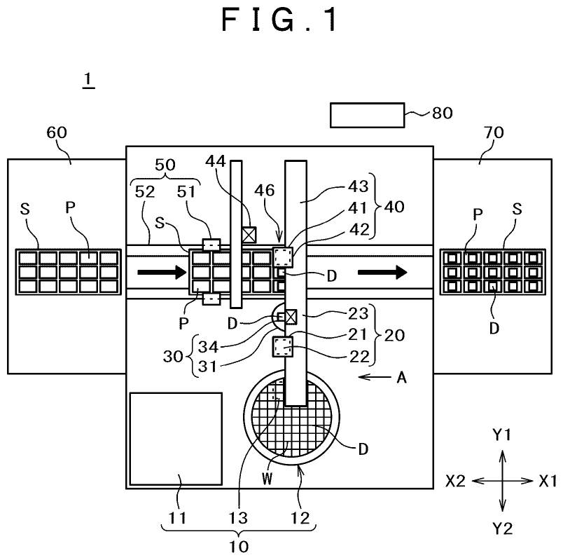

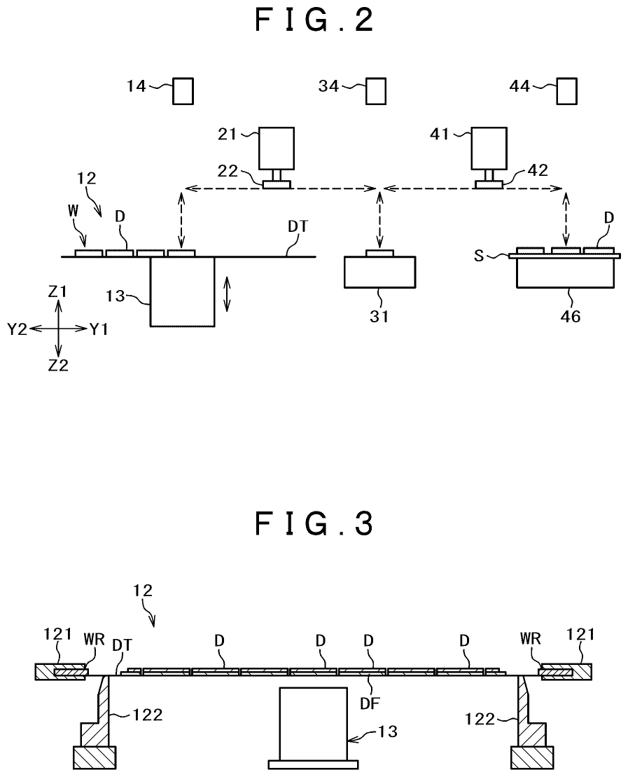

A configuration of a die bonder, which is an embodiment of a semiconductor manufacturing apparatus, will now be described with reference to FIGS. 1 to 3. FIG. 1 is a schematic top view illustrating an example of the configuration of a die bonder according to an embodiment. FIG. 2 is a diagram illustrating a schematic configuration as viewed in the direction of arrow A in FIG. 1. FIG. 3 is a schematic cross-sectional view illustrating essential parts of a wafer supply unit depicted in FIG. 1.

The die bonder 1 broadly includes a wafer supply unit 10, a pickup unit 20, an intermediate stage unit 30, a bonding unit 40, a carrier unit 50, a substrate supply unit 60, a substrate unloading unit 70, and a control unit (controller) 80. The Y2-Y1 direction is the front-back direction of the die bonder 1, the X2-X1 direction is the left-right direction, and the Z1-Z2 direction is the vertical direction. The wafer supply unit 10 is disposed on the front side of the die bonder 1, and the bonding unit 40 is disposed on the back side.

The wafer supply unit 10 includes a wafer cassette lifter 11, a wafer holding table 12, a pushup unit 13, and a wafer recognition camera 14.

The wafer cassette lifter 11 vertically moves a wafer cassette (not depicted) to a wafer transfer height. A plurality of wafer rings WR are stored in the wafer cassette. A wafer correction chute (not depicted) aligns the wafer rings WR supplied from the wafer cassette lifter 11. A wafer extractor (not depicted) removes the wafer rings WR from the wafer cassette, and supplies the wafer rings WR to the wafer holding table 12 or removes the wafer rings WR from the wafer holding table 12 and stores the wafer rings WR in the wafer cassette.

The wafer holding table 12 has an expand ring 121 and a support ring 122. The expand ring 121 holds the wafer rings WR. The support ring 122 horizontally positions a dicing tape DT that is held by the wafer rings WR. The pushup unit 13 is disposed inside the support ring 122.

A wafer W is adhered (attached) to the dicing tape DT, and the wafer W is divided into a plurality of dies D. A film-like adhesive material DF called a die attach film (DAF) is attached between the wafer W and the dicing tape DT. The adhesive material DF hardens when heated.

The wafer holding table 12 is moved in the X1-X2 and Y1-Y2 directions by a drive unit (not depicted) in order to move the dies D, which are to be picked up, to the position of the pushup unit 13. Further, the drive unit (not depicted) causes the wafer holding table 12 to rotate the wafer rings WR within the XY plane. The pushup unit 13 is moved in the vertical direction by the drive unit (not depicted). The pushup unit 13 peels off the dies D from the dicing tape DT. The wafer holding table 12 and the pushup unit 13 form a pickup device (semiconductor manufacturing apparatus). The pickup device may include the pickup unit 20.

When the dies D are to be pushed up, the wafer holding table 12 lowers the expand ring 121 that holds the wafer rings WR. In this instance, the support ring 122 does not lower. Therefore, the dicing tape DT held by the wafer rings WR is stretched to increase the spacing between the dies D. This prevents interference and contact between the dies D, and thus makes it easier to separate and push up the individual dies D. The expand ring 121 and the support ring 122 are collectively referred to as an expander. The pushup unit 13 pushes up the dies D from below, thereby promoting the peeling of the dies D and improving the performance of a collet to pick up the dies D.

The wafer recognition camera 14 recognizes the pickup position of the dies D, which are to be picked up from the wafer W, and inspects the surface of the dies D.

The pickup unit 20 has a pickup head 21 and a Y drive unit 23. The pickup head 21 is provided with a collet 22 that adsorbs and holds the peeled dies D at its tip. The pickup head 21 picks up the dies D from the wafer supply unit 10, and places the dies D on an intermediate stage 31. The Y drive unit 23 moves the pickup head 21 in the Y1-Y2 direction. The pickup unit 20 has various drive unit (not depicted) for raising, lowering, or rotating the pickup head 21, or moving the pickup head 21 in the X direction.

The intermediate stage unit 30 has a stage recognition camera 34 and the intermediate stage 31 on which the dies D are placed. The stage recognition camera 34 is used for recognizing the dies D on the intermediate stage 31. The intermediate stage 31 has a suction hole for adsorbing the dies D placed thereon. The placed dies D are temporarily held on the intermediate stage 31. The intermediate stage 31 acts as a placement stage on which the dies D are placed, and also acts as a pickup stage from which the dies D are picked up.

The bonding unit 40 has a bond head 41, a Y drive unit 43, a substrate recognition camera 44, and a bond stage 46. The bond head 41 is provided with a collet 42 that adsorbs and holds the dies D at its tip. The Y drive unit 43 moves the bond head 41 in the Y1-Y2 direction. The substrate recognition camera 44 captures an image of a position recognition mark (not depicted) on a substrate S to recognize a bond position. Here, a plurality of product areas (hereinafter referred to as the package areas P), which will eventually become one package, are formed on the substrate S. The position recognition mark is provided for each of the package areas P. When the dies D are to be placed on the substrate S, the bond stage 46 is raised to support the substrate S from below. The bond stage 46 has a suction port (not depicted) for vacuum adsorption of the substrate S, and is capable of fastening the substrate S. The bond stage 46 has a heating portion (not depicted) for heating the substrate

S. The bonding unit 40 has various driving unit (not depicted) for raising, lowering, or rotating the bond head 41 or moving the bond head 41 in the X direction.

With the above-described configuration, the bond head 41 corrects the pickup position and posture in accordance with image data obtained by the stage recognition camera 34, and picks up the dies D from the intermediate stage 31. Then, the bond head 41 performs bonding on the package areas P of the substrate S in accordance with the image data obtained by the substrate recognition camera 44, or performs bonding in a stack form on the dies already bonded on the package areas P of the substrate S.

The carrier unit 50 has carrying claws 51 and a carrying lane 52. The carrying claws 51 grip and carry the substrate S. The substrate S moves in the carrying lane 52. The substrate S moves in the X direction when a nut (not depicted) of the carrying claws 51 provided on the carrying lane 52 is driven by a ball screw (not depicted) provided along the carrying lane 52. With the above-described configuration, the substrate S moves from the substrate supply unit 60 along the carrying lane 52 to the bond position, and after bonding, moves to the substrate unloading unit 70 and delivers the substrate S to the substrate unloading unit 70.

The substrate supply unit 60 removes the substrate S, which has been stored in a carrying jig and loaded, from the carrying jig, and supplies the substrate S to the carrier unit 50. The substrate unloading unit 70 receives the substrate S, which has been carried by the carrier unit 50, and stores the substrate S in the carrying jig.

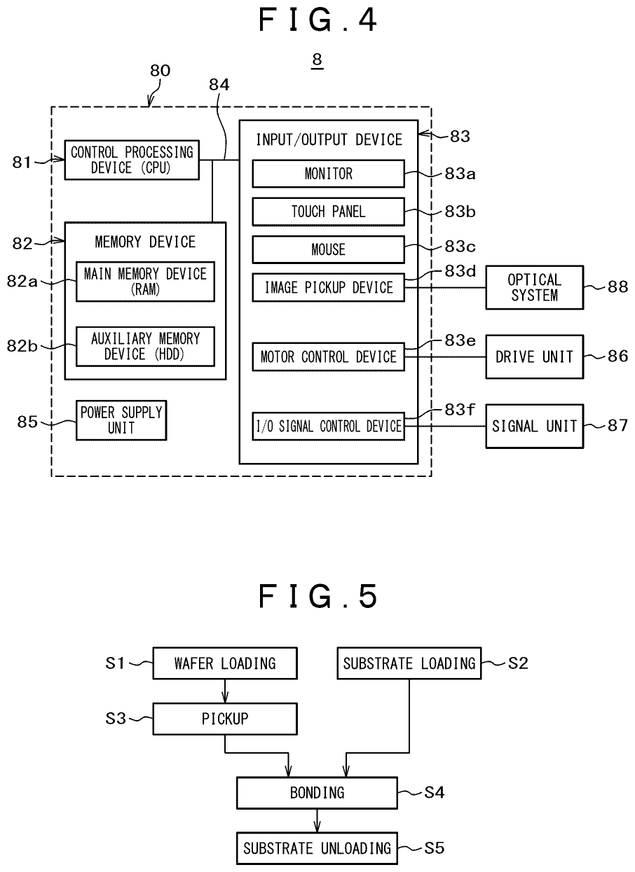

The control unit 80 will now be described with reference to FIG. 4. FIG. 4 is a block diagram illustrating a schematic configuration of a control system of the die bonder depicted in FIG. 1.

The control system 8 includes, for example, the control unit (controller) 80, a drive unit 86, a signal unit 87, and an optical system 88. The control unit 80 broadly includes a control processing device 81, a memory device 82, an input/output device 83, a bus line 84, and a power supply unit 85. The control processing device 81 is mainly formed by a CPU (Central Processing Unit). The memory device 82 includes a main memory device 82a and an auxiliary memory device 82b. The main memory device 82a is formed by a RAM (Random Access Memory) that stores, for example, processing programs. The auxiliary memory device 82b is formed by an HDD (Hard Disk Drive), an SSD (Solid State Drive), or other memory device that stores, for example, a control program, a process recipe, and control data and image data required for control. The process recipe, which functions as a program, is obtained by combining procedures and conditions in a manufacturing process of a semiconductor device, which will be described later, in such a manner as to allow the control unit 80 to execute such procedures and conditions and obtain a predetermined result.

The input/output device 83 includes a monitor 83a, a touch panel 83b, a mouse 83c, and an image pickup device 83d. The monitor 83a displays information indicating, for example, the status of a device. The touch panel 83b inputs operator instructions. The mouse 83c operates the monitor 83a. The image pickup device 83d acquires image data from the optical system 88. The input/output device 83 further includes a motor control device 83e and an I/O signal control device 83f. The motor control device 83e controls, for example, the XY table (not depicted) of the wafer supply unit 10, the ZY drive shaft of a bond head table, and the drive unit of the pushup unit 13. The I/O signal control device 83f acquires or controls signals from the signal unit 87 that includes, for example, various sensors and switches and variable resistors for controlling the brightness of lighting devices. The optical system 88 includes the wafer recognition camera 14, the stage recognition camera 34, and the substrate recognition camera 44. The control processing device 81 acquires necessary data through the bus line 84, performs calculations, controls, for example, the pickup head 21, and sends information, for example, to the monitor 83a.

A part of a method for manufacturing semiconductor device (method for manufacturing semiconductor device) by using the die bonder 1 will now be described with reference to FIG. 5. FIG. 5 is a flowchart illustrating a method for manufacturing the semiconductor device by using the die bonder depicted in FIG. 1. Operations of individual units of the die bonder 1, which are described below, are controlled by the control unit 80.

### (Wafer Loading Process (Step S1))

The wafer cassette (not depicted) containing the wafer ring WR is loaded into the wafer cassette lifter 11. The wafer supply unit 10 removes the wafer rings WR from the wafer cassette filled with the wafer rings WR, and carries the wafer rings WR to the wafer holding table 12.

### (Substrate Loading Process (Step S2))

The carrying jig storing the substrate S is loaded into the substrate supply unit 60. The substrate supply unit 60 removes the substrate S from the carrying jig. The removed substrate S is loaded into the bonding unit 40 through the carrier unit 50.

### (Pickup Process (Step S3))

After completion of step S1, the wafer holding table 12 is moved so that a desired die D can be picked up from the dicing tape DT. The wafer recognition camera 14 captures an image of the die D, and then the die D is subjected to positioning and surface inspection based on image data acquired by image capturing. Image processing is performed on the image data in order to calculate the amount of deviation (in the X, Y, and θ directions) of the die D on the wafer holding table 12 from a die position reference point of the die bonder and perform positioning. It should be noted that a predetermined position of the wafer holding table 12 is stored in advance as an initial apparatus setting indicating the die position reference point. The surface inspection of the die D is conducted by performing image processing on the image data.

The positioned die D is peeled off from the dicing tape DT by the pushup unit 13 and the pickup head 21. The die D peeled off from the dicing tape DT is adsorbed and held by the collet 22 disposed on the pickup head 21, and carried to and placed on the intermediate stage 31.

The stage recognition camera 34 captures an image of the die D on the intermediate stage 31, and then the die D is subjected to positioning and surface inspection based on image data acquired by image capturing. Image processing is performed on the image data in order to calculate the amount of deviation (in the X, Y, and θ directions) of the die D on the intermediate stage 31 from a die position reference point of the die bonder and perform positioning. It should be noted that a predetermined position of the intermediate stage 31 is stored in advance as an initial apparatus setting indicating the die position reference point. The surface inspection of the die D is conducted by performing image processing on the image data.

The pickup head 21, which has carried the die D to the intermediate stage, is returned to the wafer supply unit 10. The above-described procedure is followed to peel off the next die D from the dicing tape DT. Subsequently, the dies D are peeled off one by one from the dicing tape DT by following the procedure similar to the above.

### (Bonding Process (Step S4))

The substrate S is carried to the bond stage 46 by the carrier unit 50. An image of the substrate S placed on the bond stage 46 is captured by the substrate recognition camera 44, and then the substrate S is subjected to positioning and surface inspection based on image data acquired by image capturing. Image processing is performed on the image data in order to calculate the amount of deviation (in the X, Y, and θ directions) of the substrate S from a substrate position reference point of the die bonder 1. It should be noted that a predetermined position of the bonding unit 40 is stored in advance as an initial apparatus setting indicating the substrate position reference point. The surface inspection of the substrate S is conducted by performing image processing on the image data.

An adsorption position of the bond head 41 is corrected based on the amount of deviation of the die D on the intermediate stage 31, which has been calculated in step S3, and then the die D is adsorbed by the collet 42. The bond head 41, which has adsorbed the die D from the intermediate stage 31, bonds the die D to a predetermined location on the substrate S supported by the bond stage 46. In this instance, the predetermined location of the substrate S is a package area P of the substrate S, or an area where an element is already placed and another element is to be bonded in addition to that, or a bonding area for an element to be bonded in a stack form. An image of the die D bonded to the substrate S is captured by the substrate recognition camera 44, and then inspection is performed, for example, to determine whether the die D has been bonded at a desired position based on the image data acquired by image capturing.

The bond head 41, which has bonded the die D to the substrate S, is returned to the intermediate stage 31. The above-described procedure is followed to pick up the next die D from the intermediate stage 31 and bond the next die D to the substrate S. The above is repeated to bond the dies D to all the package areas P of the substrate S.

### (Substrate Unloading Process (Step S5))

The substrate S, to which the dies D are bonded, is carried to the substrate unloading unit 70. In the substrate unloading unit 70, the substrate S is removed from the carrying claws 51 and stored in the carrying jig. The carrying jig storing the substrate S is unloaded from the die bonder 1.

As described above, the dies D are mounted on the substrate S and unloaded from the die bonder 1. Subsequently, for example, the carrying jig storing the substrate S, on which the dies D are mounted, is carried to a wire bonding process, and then the electrodes of the dies D are electrically connected to the electrodes of the substrate S, for example, via Au wires. The substrate S is then carried to a molding process, where the die D and the Au wires are sealed with a mold resin (not depicted) to complete a semiconductor package.

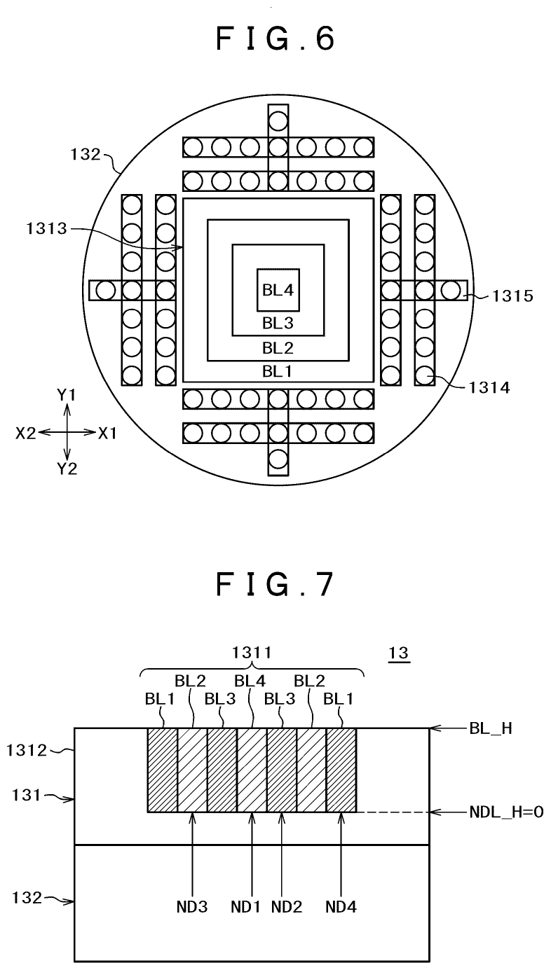

The pushup unit 13 will now be described with reference to FIGS. 6 and 7. FIG. 6 is a top view of a pushup unit depicted in FIG. 2. FIG. 7 is a schematic cross-sectional view of essential parts of the pushup unit depicted in FIG. 6.

The pushup unit 13 includes a first unit 131 and a second unit 132. The first unit 131 is to be attached to the second unit 132. The second unit 132 is a common part that is used regardless of the type. The first unit 131 is a part that can be replaced for each type. The first unit 131 is configured such that a block section 1311 is provided on a dome 1312 having a cylindrical shape. An opening 1313 is provided at the center of the upper surface of the dome 1312 to allow the block section 1311 to move up and down. A plurality of suction ports 1314 and a plurality of grooves 1315 connecting the plurality of suction ports 1314 are provided in the outer periphery of the opening 1313 in the upper surface of the dome 1312. The inside of the suction ports 1314 is depressurized by a suction mechanism (not depicted) when the pushup unit 13 is to be raised to bring its upper surface into contact with the rear surface of the dicing tape DT. In this instance, the rear surface of the dicing tape DT is sucked downward and brought into close contact with the upper surface of the dome 1312.

The block section 1311 has a plurality of blocks that push the dicing tape DT upward. An example depicted here indicates a case where the block section 1311 has four blocks BL1 to BL4. The innermost block BL4 is shaped like a rectangular prism. The three outer blocks BL1 to BL3 have a rectangular cylindrical shape, and have rectangular openings penetrating in the Z1-Z2 direction. The block BL2, which is smaller in size than the block BL1, is disposed inside the block BL1. Additionally, the block BL3, which is smaller in size than the block BL2, is disposed inside the block BL2. Additionally, the block BL4, which is smaller in size than the block BL3, is disposed inside the block BL3.

The block BL1, which is the outermost of the four blocks BL1 to BL4, is slightly smaller in diameter than the outer circumference of the dies D to be peeled off. As a result, the outer circumferential corner of the upper surface of the block BL1 is positioned slightly inside the outer edge of the dies D. This ensures that the force for peeling the dies D and the dicing tape DT from each other is concentrated at a point (the outermost periphery of dies D) that serves as the starting point for peeling the two apart.

The second unit 132, which serves as a drive unit, has four drive shafts ND4 to ND1 that independently drive the blocks BL1 to BL4 in the up-down direction. For example, the drive shafts ND1 to ND4 each include a motor and a plunger mechanism. The plunger mechanism converts the rotation of the motor into a vertical motion. The tips (upper ends) of the drive shafts ND4 to ND1, which are to be connected to the blocks BL1 to BL4, are called needles. The needles of the drive shafts ND1 to ND4 are called NDL1 to NDL4, respectively.

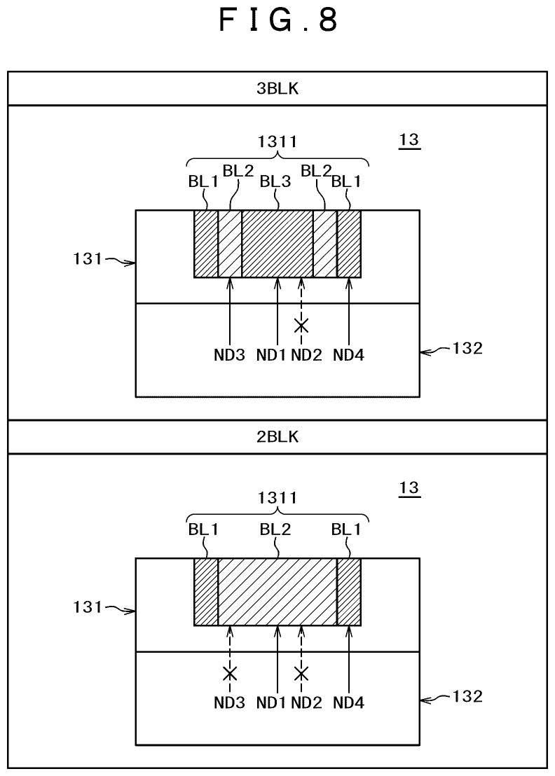

Alternatively, the number of blocks in the first unit 131 may be smaller than four. In such an alternative case, some of the drive shafts ND1 to ND4 of the second unit 132 are operative while the others are inoperative. This will be described with reference to FIG. 8. FIG. 8 is a schematic diagram illustrating an example where blocks and drive shafts are connected in a case where the number of blocks is smaller than four.

In a case where the three blocks BL1 to BL3 are used, for example, in a 3BLK type pushup unit 13 depicted in FIG. 8, the block BL1 is driven by the drive shaft ND4, the block BL2 is driven by the drive shaft ND3, and the block BL3 is driven by the drive shaft ND1. That is to say, the drive shaft ND2 is not allowed to operate. Alternatively, the block BL3 may be driven by the drive shaft ND2 instead of the drive shaft ND1.

In a case where the two blocks BL1, BL2 are used, for example, in a 2BLK type pushup unit 13 depicted in FIG. 8, the block BL1 is driven by the drive shaft ND4, and the block BL2 is driven by the drive shaft ND1. That is to say, the drive shaft ND2 and the drive shaft ND3 are not allowed to operate. Alternatively, the block BL2 may be driven by the drive shaft ND3 instead of the drive shaft ND1.

Since the blocks BL1 to BL4 of the pushup unit 13 are each able to operate independently, the pushup unit 13 is able to perform various operations (pushup sequences). The pushup sequences of the plurality of blocks include a plurality of steps.

For example, the pushup unit 13 is capable of operating to simultaneously push up the blocks BL1 to BL4 in a first step, simultaneously push up blocks BL2 to BL4 in a second step, simultaneously push up blocks BL3, BL4 in a third step, and push up the block BL4 in a fourth step. In this document, the above operation is called a multi-stage operation. The multi-stage operation in the four blocks is called a multi-stage operation in a four-stage block.

Further, the pushup unit 13 is capable of operating to simultaneously push up the blocks BL1 to BL4 in the first step, lower the block BL1 in the second step, lower the block BL2 in the third step, and lower the block BL3 in the fourth step. In this document, the above operation is called a reverse multi-stage operation. The reverse multi-stage operation in the four blocks is called a reverse multi-stage operation in the four-stage block.

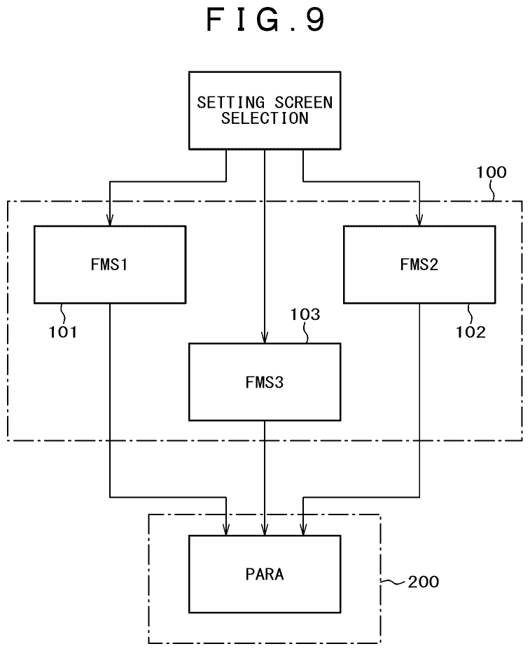

A method for setting a time chart recipe 200 will now be described with reference to FIG. 9. The time chart recipe 200 defines the operation of the pushup unit 13. The time chart recipe 200 forms a part of the process recipe. FIG. 9 is a diagram illustrating the flow of setting the time chart recipe from a setting screen.

For example, a setting screen 101 for a multi-stage operation (FMS1), a setting screen 102 for a reverse multi-stage operation (FMS2), and a setting screen 103 for a general-purpose operation (FMS3) are available as the setting screen 100. The setting screen 103 is capable of setting the multi-stage operation and the reverse multi-stage operation. The operator uses, for example, the touch panel 83b to select one of a plurality of setting screens 101, 102, 103. The control unit 80 displays the selected setting screen on the monitor 83a. Then, the operator inputs settings for items on the setting screen. The control unit 80 sets pushup parameters (PARA) of the time chart recipe 200 (creates the time chart recipe 200) in accordance with the inputted settings. The control unit 80 is able to change a pushup operation by rewriting (setting) the time chart recipe 200 in real time in accordance with information acquired, for example, from the sensors and images captured by the recognition cameras.

The control unit 80 is configured to control the drive shafts ND4 to ND1, which drive the blocks BL1 to BL4, respectively, in accordance with the pushup parameters set in the time chart recipe. The pushup parameters are set when, for example, values are inputted from the setting screen displayed on the monitor 83a. The pushup parameters include the pushup height, pushup velocity, and timer value of each of the needles NDL1 to NDL4. In the above instance, the pushup height indicates the position (height) of the tips of the needles NDL1 to NDL4. The height of the needles NDL1 to NDL4 is referred to as NDL1_H to NDL4_H, and occasionally referred to collectively as NDL_H. When the upper ends of the blocks BL1 to BL4 are positioned on the upper surface of the dome 1312, NDL_H=0. The height of the needles NDL1 to NDL4 is sometimes referred to as the height of the blocks BL4 to BL1. The upper surface of the dome 1312 is used as the reference for determining the height of the blocks BL4 to BL1.

The pushup velocity (V) is the velocity of ascent (VU) or the velocity of descent (VD) of the needles NDL1 to NDL4 (blocks BL4 to BL1).

The timer value (T) indicates the length of time between the end of ascent or descent of the needles NDL1 to NDL4 in a step and the start of ascent or descent of the needles NDL1 to NDL4 (blocks BL4 to BL1) in the next step. It can be said that the timer value is an operation time difference (interval time) for adjusting the processing time between the individual blocks. The length of one step is the time it takes for the needles NDL1 to NDL4 (blocks BL4 to BL1) to reach a predetermined height from a stopped state. Instead of the timer value, the length (time) of one step may alternatively be used as a parameter. In such an alternative case, the above-mentioned time includes the time taken for the needles NDL1 to NDL4 (blocks BL4 to BL1) to reach the predetermined height from the stopped state and the time during which they are stopped while maintaining such height.

Examples of pushup parameters set in the time chart recipe for the pushup unit 13 having four drive shafts are given below. Here, it should be noted that n=1 to 4, and that m=1 to 4.
NDLm_H_Sn: A parameter representing the height (H) of a needle m (NDLm) in the nth step (Sn).
NDLm_VU_Sn: A parameter representing the pushup velocity of ascent (VU) of the needle m (NDLm) in the nth step (Sn).
NDLm_VD_Sn: A parameter representing the pushup velocity of descent (VD) of the needle m (NDLm) in the nth step (Sn).
NDLm_T_Sn: A parameter representing the timer value (T) of the needle m (NDLm) in the nth step (Sn).

### [FMS1 Setting Example]

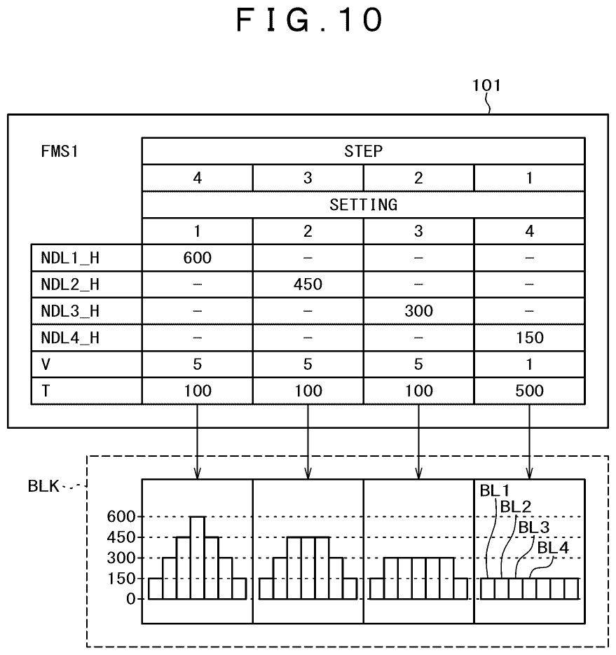

A setting example of the setting screen 101 for the multi-stage operation in the pushup unit 13 depicted in FIG. 7 and its operation will now be described with reference to FIG. 10. FIG. 10 is a diagram illustrating an example of settings in the setting screen for a multi-stage operation in a four-stage block and the height of the blocks based on the settings.

The operator operates the touch panel 83b to select the setting screen 101. The control unit 80 displays the setting screen 101 on the monitor 83a. The setting screen 101 allows NDL1_H [μm] to be inputted as a first setting, allows NDL2_H [μm] to be inputted as a second setting, allows NDL3_H [μm] to be inputted as a third setting, and allows NDL4_H [μm] to be inputted as a fourth setting. Data cannot be inputted into a “−” field. The pushup velocity [mm/sec] and the timer value [msec] can be inputted as the first to fourth settings.

NDL1_H, NDL2_H, NDL3_H and NDL4_H of each step can be set by one piece of data. In the setting screen 101, “600” is inputted for NDL1_H as the first setting, “450” is inputted for NDL2_H as the second setting, “300” is inputted for NDL3_H as the third setting, and “150” is inputted for NDL4_H as the fourth setting.

The pushup velocity and timer value for each step can be set by data common to the needles NDL1 to NDL4. In the setting screen 101, a pushup velocity of “5” and a timer value of “100” are inputted as the first to third settings. A pushup velocity of “1” and a timer value of “500” are inputted as the fourth setting.

Pushup parameter settings based on the values inputted into the setting screen 101 will now be described.

### (Fourth Setting: Setting in First Step (STEP 1))

When “150” is inputted for NDL4_H, the control unit 80 sets “150” for NDL4_H_S1, and also sets the same value, namely, “150,” for NDL1_H_S1, NDL2_H_S1, and NDL3_H_S1.

When “1” is inputted as the pushup velocity, the control unit 80 sets “1” for NDL1_VU_S1, NDL2_VU_S1, NDL3_VU_S1, and NDL4_VU_S1. Further, when “1” is inputted as the pushup velocity, the control unit 80 sets “1” for NDL1_VD_S1, NDL2_VD_S1, NDL3_VD_S1, and NDL4_VD_S1.

When “500” is inputted as the timer value, the control unit 80 sets “500” for NDL1_T_S1, NDL2_T_S1, NDL3_T_S1, and NDL4_T_S1.

### (Third Setting: Setting in Second Step (STEP 2))

When “300” is inputted for NDL3_H, the control unit 80 sets “300” for NDL3_H_S2, and also sets the same value, namely, “300,” for NDL1_H_S2 and NDL2_H_S2. Further, the control unit 80 sets NDLA_H_S2 to “150,” which is the same value as the fourth setting for NDL4_H_S1.

When “5” is inputted as the pushup velocity, the control unit 80 sets “5” for NDL1_VU_S2, NDL2_VU_S2, NDL3_VU_S2, and NDL4_VU_S2. Further, when “5” is inputted as the pushup velocity, the control unit 80 sets “5” for NDL1_VD_S2, NDL2_VD_S2, NDL3_VD_S2, and NDL4_VD_S2.

When “100” is inputted as the timer value, the control unit 80 sets “100” for NDL1_T_S2, NDL2_T_S2, NDL3_T_S2, and NDL4_T_S2.

### (Second Setting: Setting in Third Step (STEP 3))

When “450” is inputted for NDL2_H, the control unit 80 sets “450” for NDL2_H_S3, and also sets the same value, namely, “450,” for NDL1_H_S3. Further, the control unit 80 sets NDL3_H_S3 to “300,” which is the same value as the third setting for NDL3_H_S2, and sets NDLA_H_S3 to “150,” which is the same value as the fourth setting for NDL4_H_S1.

When “5” is inputted as the pushup velocity, the control unit 80 sets “5” for NDL1_VU_S3, NDL2_VU_S3, NDL3_VU_S3, and NDL4_VU_S3. Further, when “5” is inputted as the pushup velocity, the control unit 80 sets “5” for NDL1_VD_S3, NDL2_VD_S3, NDL3_VD_S3, and NDL4_VD_S3.

When “100” is inputted as the timer value, the control unit 80 sets “100” for NDL1_T_S3, NDL2_T_S3, NDL3_T_S3, and NDL4_T_S3.

### (First Setting: Setting in Fourth Step (STEP 4))

When “600” is inputted for NDL1_H, the control unit 80 sets “600” for NDL1_H_S4. Further, the control unit 80 sets NDL2_H_S4 to “450,” which is the same value as the second setting for NDL2_H_S3, sets NDL3_H_S4 to “300,” which is the same value as the third setting for NDL3_H_S2, and sets NDL4_H_S4 to “150,” which is the same value as the fourth setting for NDL4_H_S1.

When “5” is inputted as the pushup velocity, the control unit 80 sets “5” for NDL1_VU_S4, NDL2_VU_S4, NDL3_VU_S4, and NDL4_VU_S4. Further, when “5” is inputted as the pushup velocity, the control unit 80 sets “5” for NDL1_VD_S4, NDL2_VD_S4, NDL3_VD_S4, and NDL4_VD_S4.

When “100” is inputted as the timer value, the control unit 80 sets “100” for NDL1_T_S4, NDL2_T_S4, NDL3_T_S4, and NDL4_T_S4.

As described above, when the pushup parameters are set, the blocks BL1 to BL4 are pushed up to a height of 150 μm in the first step as depicted within the dashed line BLK in FIG. 10. In the second step, the blocks BL2 to BL4 are pushed up to a height of 300 μm. In the third step, the blocks BL3, BL4 are pushed up to a height of 450 μm. In the fourth step, the block BL4 is pushed up to a height of 600 μm.

It should be noted that, as depicted within the dashed line BLK in FIG. 10, the control unit 80 may cause the setting screen 101 to display the height of the blocks BL1 to BL4 in the first to fourth steps in accordance with the set parameters.

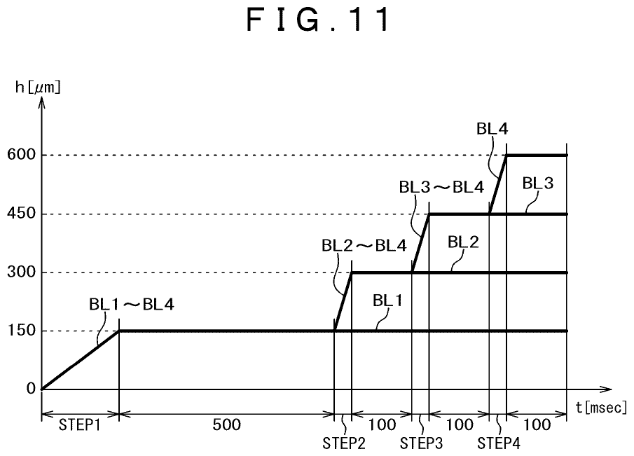

Operations of the individual blocks, which are set in the setting screen 101 depicted in FIG. 10, will now be described with reference to FIG. 11. FIG. 11 is a diagram illustrating the timing of block operations performed in a pushup sequence based on the settings in the setting screen depicted in FIG. 10.

First of all, a pickup operation performed before the operation of each block of the pushup unit 13 will be described. The pickup operation starts when a target die D on the dicing tape DT is positioned by the pushup unit 13 and the collet 22. Upon completion of positioning, the dicing tape DT is vacuumed through the suction ports 1314 of the pushup unit 13 and the gaps between the blocks BL1 to BL4 until it is adsorbed to the upper surface of the pushup unit 13. In this instance, the upper surfaces of the blocks BL1 to BL4 are flush with the upper surface of the dome 1312 (initial position). In this state, vacuum is supplied from a vacuum source so that the collet 22 is vacuumed downward and landed on the device surface of the die D.

### First Step (STEP 1):

The blocks BL1 to BL4 ascend to a height of 150 μm at a velocity of 1 mm/sec, and then stop. After a lapse of 100 msec since the end of the first step (stoppage of blocks BL1 to BL4), the processing proceeds to the second step.

### Second Step (STEP 2):

The blocks BL2 to BL4 ascend to a height of 300 μm at a velocity of 5 mm/sec, and then stop. After a lapse of 100 msec since the end of the second step (stoppage of blocks BL2 to BL4), the processing proceeds to the third step.

### Third Step (STEP 3):

The blocks BL3, BL4 ascend to a height of 450 μm at a velocity of 5 mm/sec, and then stop. After a lapse of 100 msec since the end of the third step (stoppage of blocks BL3, BL4), the processing proceeds to the fourth step.

### Fourth Step (STEP 4):

The block BL4 ascends to a height of 600 μm at a velocity of 5 mm/sec, and then stops. After a lapse of 100 msec since the end of the fourth step (stoppage of block BL4), the collet 22 begins to ascend.

### [FMS2 Setting Example]

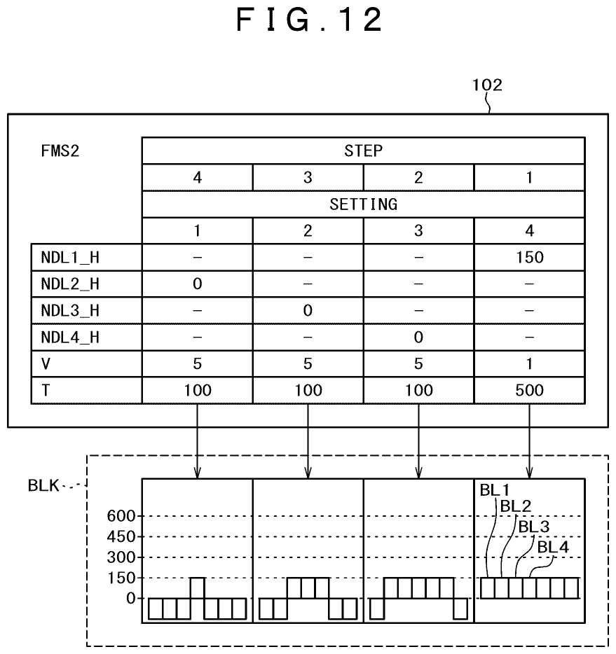

A setting example of the setting screen for the reverse multi-stage operation in the pushup unit 13 depicted in FIG. 7 and its operation will now be described with reference to FIG. 12. FIG. 12 is a diagram illustrating an example of settings in the setting screen for a reverse multi-stage operation and the height of the blocks based on the settings.

The operator operates the touch panel 83b to select the setting screen 102. The control unit 80 displays the setting screen 102 on the monitor 83a. The setting screen 102 allows NDL2_H [μm] to be inputted as the first setting, allows NDL3_H [μm] to be inputted as the second setting, allows NDL4_H [μm] to be inputted as the third setting, and allows NDL1_H [μm] to be inputted as the fourth setting. The pushup velocity [mm/sec] and the timer value [msec] can be inputted as the first to fourth settings.

NDL1_H, NDL2_H, NDL3_H and NDL4_H of each step can be set by one piece of data. In the setting screen 102, “0” is inputted for NDL2_H as the first setting, “0” is inputted for NDL3_H as the second setting, “0” is inputted for NDL4_H as the third setting, and “150” is inputted for NDL1_H as the fourth setting.

The pushup velocity and timer value for each step can be set by data common to the needles NDL1 to NDL4. In the setting screen 102, a pushup velocity of “5” and a timer value of “100” are inputted as the first to third settings. A pushup velocity of “1” and a timer value of “500” are inputted as the fourth setting.

The pushup parameter settings based on the values inputted into the setting screen 102 will now be described.

### (Fourth Setting: Setting in First Step)

When “150” is inputted as NDL1_H, the control unit 80 sets “150” for NDL1_H_S1, and also sets the same value, namely, “150,” for NDL2_H_S1, NDL3_H_S1, and NDL4_H_S1.

When “1” is inputted as the pushup velocity, the control unit 80 sets “1” for NDL1_VU_S1, NDL2_VU_S1, NDL3_VU_S1, and NDL4_VU_S1. Further, when “1” is inputted as the pushup velocity, the control unit 80 sets “1” for NDL1_VD_S1, NDL2_VD_S1, NDL3_VD_S1, and NDL4_VD_S1.

When “500” is inputted as the timer value, the control unit 80 sets “500” for NDL1_T_S1, NDL2_T_S1, NDL3_T_S1, and NDL4_T_S1.

### (Third Setting: Setting in Second Step)

When “0” is inputted for NDL4_H, the control unit 80 sets “0” for NDL4_H_S2, and additionally sets NDL1_H_S2, NDL2_H_S2, and NDL3_H_S2 to “150,” which is the same value as the fourth setting for NDL1_H_S1.

When “5” is inputted as the pushup velocity, the control unit 80 sets “5” for NDL1_VU_S2, NDL2_VU_S2, NDL3_VU_S2, and NDL4_VU_S2. Further, when “5” is inputted as the pushup velocity, the control unit 80 sets “5” for NDL1_VD_S2, NDL2_VD_S2, NDL3_VD_S2, and NDL4_VD_S.

When “100” is inputted as the timer value, the control unit 80 sets “100” for NDL1_T_S2, NDL2_T_S2, NDL3_T_S2, and NDL4_T_S2.

### (Second Setting: Setting in Third Step)

When “0” is inputted for NDL3_H, the control unit 80 sets “0” for NDL3_H_S3, and additionally sets NDL1_H_S3 and NDL2_H_S3 to “150,” which is the same value as the fourth setting for NDL1_H_S1. Further, the control unit 80 sets NDL4_H_S3 to “0,” which is the same value as the third setting for NDL4_H_S2.

When “5” is inputted as the pushup velocity, the control unit 80 sets “5” for NDL1_VU_S3, NDL2_VU_S3, NDL3_VU_S3, and NDL4_VU_S3. Further, when “5” is inputted as the pushup velocity, the control unit 80 sets “5” for NDL1_VD_S3, NDL2_VD_S3, NDL3_VD_S3, and NDL4_VD_S3.

When “100” is inputted as the timer value, the control unit 80 sets “100” for NDL1_T_S3, NDL2_T_S3, NDL3_T_S3, and NDL4_T_S3.

### (First Setting: Setting in Fourth Step)

When “0” is inputted for NDL2_H, the control unit 80 sets “0” for NDL2_H_S4, and additionally sets NDL1_H_S4 to “150,” which is the same value as the fourth setting for NDL1_H_S1. Further, the control unit 80 sets NDL3_T_S4 to “0,” which is the same value as the second setting for NDL3_H_S3, and sets NDL4_H_S4 to “0,” which is the same value as the third setting for NDL4_H_S2.

When “5” is inputted as the pushup velocity, the control unit 80 sets “5” for NDL1_VU_S4, NDL2_VU_S4, NDL3_VU_S4, and NDL4_VU_S4. Further, when “5” is inputted as the pushup velocity, the control unit 80 sets “5” for NDL1_VD_S4, NDL2_VD_S4, NDL3_VD_S4, and NDL4_VD_S4.

When “100” is inputted as the timer value, the control unit 80 sets “100” for NDL1_T_S4, NDL2_T_S4, NDL3_T_S4, and NDL4_T_S4.

As described above, when the pushup parameters are set, the blocks BL1 to BL4 are pushed up to a height of 150 μm in the first step as depicted within the dashed line BLK in FIG. 12. In the second step, the block BL1 is lowered to a height of 0 μm. In the third step, the block BL2 is lowered to a height of 0 μm. In the fourth step, the block BL3 is lowered to a height of 0 μm.

It should be noted that, as depicted within the dashed line BLK in FIG. 12, the control unit 80 may cause the setting screen 102 to display the height of the blocks BL1 to BL4 in the first to fourth steps in accordance with the set parameters.

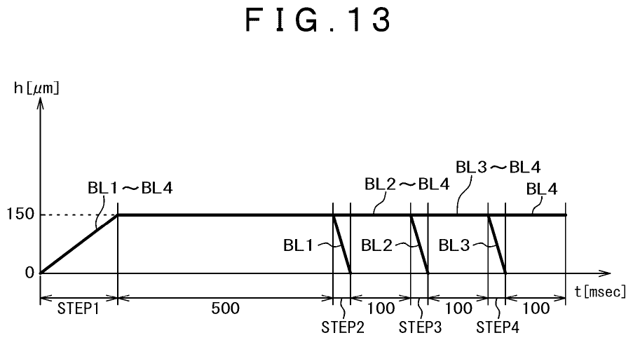

Operations of the individual blocks, which are set in the setting screen 102 depicted in FIG. 12, will now be described with reference to FIG. 13. FIG. 13 is a diagram illustrating the timing of block operations performed in a pushup sequence based on the settings in the setting screen depicted in FIG. 12.

### First Step (STEP 1):

The blocks BL1 to BL4 ascend to a height of 150 μm at a velocity of 1 mm/sec, and then stop. After a lapse of 500 msec since the end of the first step (stoppage of blocks BL1 to BL4), the processing proceeds to the second step.

### Second Step (STEP 2):

The block BL1 descends to a height of 0 μm at a velocity of 5 mm/sec, and then stops. After a lapse of 100 msec since the end of the second step (stoppage of block BL1), the processing proceeds to the third step.

Third Step (STEP 3):

The block BL2 descends to a height of 0 μm at a velocity of 5 mm/sec, and then stops. After a lapse of 100 msec since the end of the third step (stoppage of block BL2), the processing proceeds to the fourth step.

### Fourth Step (STEP 4):

The block BL3 descends to a height of 0 μm at a velocity of 5 mm/sec, and then stops. After a lapse of 100 msec since the end of the fourth step (stoppage of block BL3), the collet 22 begins to ascend.

### [FMS2 Three-stage Block Setting Example]

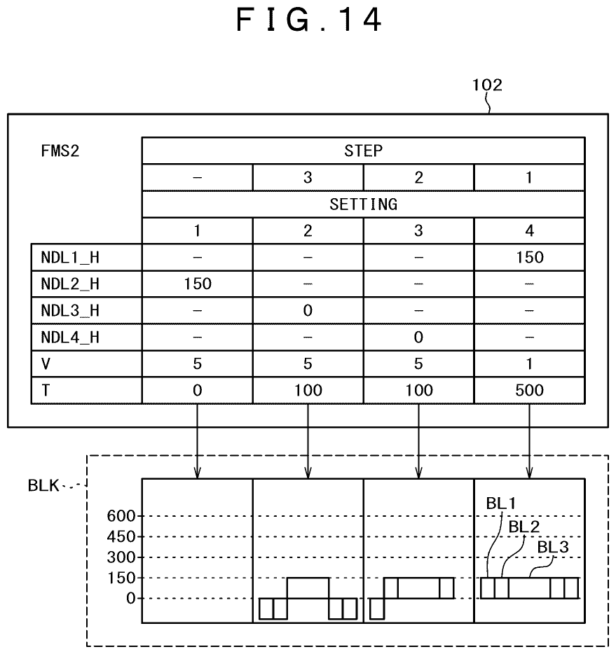

A setting example of the setting screen 102 for the reverse multi-stage operation in the 3BLK type pushup unit 13 depicted in FIG. 8 and its operation will now be described with reference to FIG. 14. FIG. 14 is a diagram illustrating an example of settings in the setting screen for the reverse multi-stage operation in a three-stage block and the height of the blocks based on the settings.

The 3BLK-type pushup unit 13 does not use the needle NDL2. Accordingly, as the first setting for NDL2_H, the operator inputs “150,” which is the same value as the fourth setting for NDL1_H, inputs a pushup velocity of “5,” and inputs a timer value of “0.” In this instance, the same values as those in the setting screen 102 depicted in FIG. 12 are inputted as the second to fourth settings. By using the second to fourth settings, the control unit 80 sets the same pushup parameters as those for the pushup unit performing the reverse multi-stage operation depicted in FIG. 12, except for the parameters related to the needle NDL2.

The pushup parameter settings based on the values inputted into the setting screen 102 will now be described. It should be noted that the first setting for NDL2_H is the same as the fourth setting for NDL1_H, and that the first setting for the timer value is “0.” This indicates that the needle NDL2 is not used, and the control unit 80 sets “0” as the parameters related to the needle NDL2.

### [FMS2 Two-stage Block Setting Example]

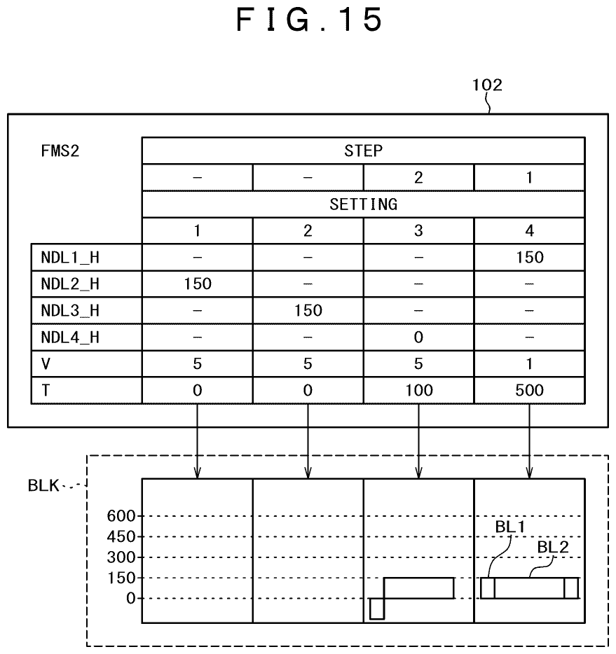

A setting example of the setting screen for the reverse multi-stage operation in the 2BLK type pushup unit 13 and its operation will now be described with reference to FIG. 15. FIG. 15 is a diagram illustrating an example of settings in the setting screen for the reverse multi-stage operation in a two-stage block and the height of the blocks based on the settings.

The 2BLK-type pushup unit 13 does not use the needles NDL2 and NDL3. Accordingly, as the first setting for NDL2_H, the operator inputs “150,” which is the same value as the fourth setting for NDL1_H, inputs a pushup velocity of “5,” and inputs a timer value of “0.” Further, as the second setting for the needle NDL3, the operator inputs “150,” which is the same value as the fourth setting for NDL1_H, inputs a pushup velocity of “5,” and inputs a timer value of “0.” In this instance, the same values as those in the setting screen depicted in FIG. 12 are inputted as the third and fourth settings. By using the third and fourth settings, the control unit 80 sets the same pushup parameters as those for the pushup unit performing the reverse multi-stage operation depicted in FIG. 12, except for the parameters related to the needles NDL2 and NDL3.

The pushup parameter settings based on the values inputted into the setting screen 102 will now be described. It should be noted that the first setting for NDL2_H is the same as the fourth setting for NDL1_H, and that the first setting for the timer value is “0.” This indicates that the needle NDL2 is not used, and the control unit 80 sets “0” as the parameters related to the needle NDL2. Further, the second setting for NDL3_H is the same as the fourth setting for NDL1_H, and the second setting for the timer value is “0.” This indicates that the needle NDL3 is not used, and the control unit 80 sets “0” as the parameters related to the needle NDL3.

### [Another Example of FMS2 Four-stage Block]

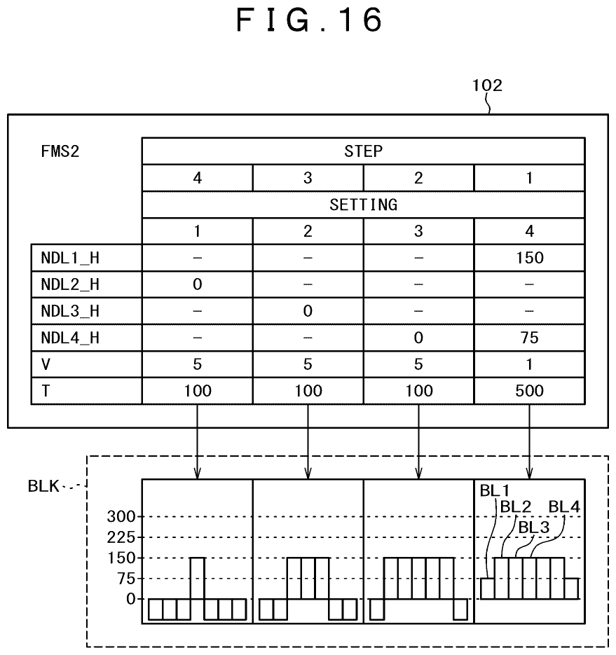

Another setting example of the setting screen 102 for the reverse multi-stage operation in the pushup unit 13 depicted in FIG. 7 and its operation will now be described with reference to FIG. 16. FIG. 16 is a diagram illustrating another example of settings in the setting screen for the reverse multi-stage operation in the four-stage block and the height of the blocks based on the settings.

An optional setting is available from the setting screen 102 depicted in FIG. 16 so that NDL4_H [μm] can be additionally inputted as the fourth setting in the setting screen 102 depicted in FIG. 12.

The pushup velocity and the timer value are to be inputted in the same manner as in the setting screen 102 depicted in FIG. 12. The first to third settings for NDL1_H, NDL2_H, NDL3_H, and NDL4_H are to be inputted in the same manner as in the setting screen 102 depicted in FIG. 12. A value of “150” is inputted as the fourth setting for NDL1_H, and a value of “75” is inputted as the fourth setting for NDL4_H. A pushup velocity of “1” and a timer value of “500” are inputted as the fourth setting.

The settings for the pushup parameters based on the values inputted as the first to third settings in the setting screen 102 are the same as those depicted in FIG. 12. The settings for the parameter based on the fourth setting will now be described.

### (Fourth Setting: Setting in First Step)

When “150” is inputted for NDL1_H, “150” is set for NDL1_H_S1, and NDL2_H2_S1 and NDL3_H_S1 are set to “150,” which is the same value as for NDL1_H_S1. When “75” is inputted for NDL4_H, the control unit 80 sets “75” for NDL4_H_S1.

When “1” is inputted as the pushup velocity, the control unit 80 sets “1” for NDL1_VU_S1, NDL2_VU_S1, NDL3_VU_S1, and NDL4_VU_S1. Further, when “1” is inputted as the pushup velocity, the control unit 80 sets “1” for NDL1_VD_S1, NDL2_VD_S1, NDL3_VD_S1, and NDL4_VD_S1.

When “500” is inputted as the timer value, the control unit 80 sets “500” for NDL1_T_S1, NDL2_T_S1, NDL3_T_S1, and NDL4_T_S1.

As described above, when the pushup parameters are set, in the first step as depicted within the dashed line BLK in FIG. 16, the blocks BL1 to BL3 are pushed up to a height of 150 μm, and the fourth block BL4 is pushed up to a height of 75 μm. Since the first to third settings are the same as those in the setting screen 102 depicted in FIG. 12, the operations performed in the second to fourth steps are the same as indicated on the setting screen 102.

It should be noted that, as depicted within the dashed line BLK in FIG. 16, the control unit 80 may cause the setting screen 102 to display the height of the blocks BL1 to BL4 in the first to fourth steps in accordance with the set parameters.

### [FMS3 Setting Example]

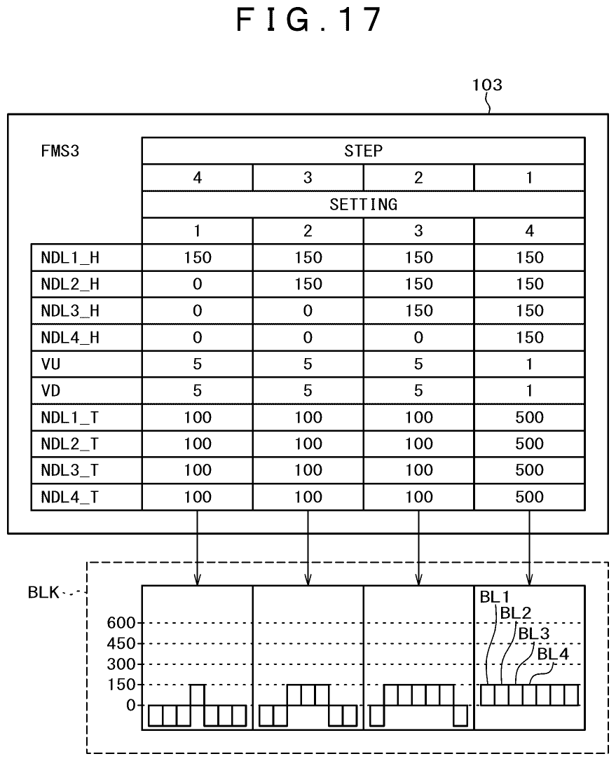

A setting example of the setting screen for the general-purpose operation in the pushup unit 13 depicted in FIG. 7 and its operation will now be described with reference to FIG. 17. FIG. 17 is a diagram illustrating an example of settings in the setting screen for a general-purpose operation in the four-stage block and the height of the blocks based on the settings.

The operator operates the touch panel 83b to select the setting screen 103. The control unit 80 displays the setting screen 103 on the monitor 83a. The setting screen 103 is configured such that NDL1_H [μm], NDL2_H [μm], NDL3_H [μm], NDL4_H [μm], the pushup velocity [mm/sec], and the pushup speed (descent) [mm/sec] can be inputted for each step. Additionally, NDL1_T [msec], NDL2_T [msec], NDL3_T [msec], and NDL4_T [msec] can be inputted for each step. The ascending pushup velocity (VU) and the descending pushup velocity (VD) are set to values common to the needles NDL1 to NDL4.

The setting screen 103 differs from the setting screens 101, 102 in that the former requires a setting input for all items in each step. The pushup parameters inputted and set in the setting screen 103 depicted in FIG. 17 are the same as the pushup parameters inputted and set in the setting screen 102 depicted in FIG. 12.

### [Another Example of FMS3]

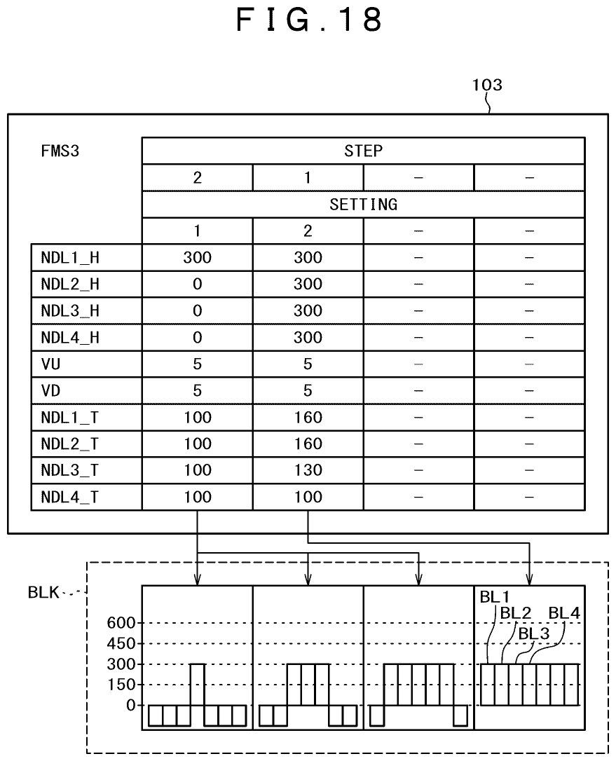

Another setting example of the setting screen 103 for the reverse multi-stage operation in the pushup unit 13 depicted in FIG. 7 and its operation will now be described with reference to FIG. 18. FIG. 18 is a diagram illustrating another example of settings in the setting screen for the reverse multi-stage operation in the four-stage block and the height of the blocks based on the settings. As the first setting, “300” is inputted for NDL1_H, and “0” is inputted for NDL2_H to NDL4_H. A value of “5” is inputted as the ascending pushup velocity (VU), and a value of “5” is inputted as the descending pushup velocity (VD). A value of “100” is inputted for NDL1_T to NDL4_T. As the second setting, “300” is inputted for NDL1_H to NDL4_H. A value of “5” is inputted for VU and VD. A value of “160” is inputted for NDL1_T, a value of “160” is inputted for NDL2_T, a value of “130” is inputted for NDL3_T, and a value of “100” is inputted for NDL4_T.

The pushup parameter settings based on the values inputted into the setting screen 103 will now be described.

### (Second Setting: Setting in First Step)

When “300” is inputted for NDL1_H to NDL4_H, the control unit 80 sets “300” for NDL1_H_S1, NDL2_H_S1, NDL3_H_S1, and NDL4_H_S1.

When “5” is inputted for VU, the control unit 80 sets “5” for NDL1_VU_S1, NDL2_VU_S1, NDL3_VU_S1, and NDL4_VU_S1. Further, when “5” is inputted for VD, the control unit 80 sets “5” for NDL1_VD_S1, NDL2_VD_S1, NDL3_VD_S1, and NDL4_VD_S1.

When “160” is inputted for NDL1_T, “160” is inputted for NDL2_T, “130” is inputted for NDL3_T, and “100” is inputted for NDL4_T, the control unit 80 sets “160” for NDL1_T_S1, sets “160” for NDL2_T_S1, sets “130” for NDL3_T_S1, and sets “100” for NDL4_T_S1.

### (First Setting: Setting in Second Step)

When “300” is inputted for NDL1_H, the control unit 80 sets “300” for NDL1_H_S2. When “0” is inputted for NDL2_H to NDL4_H, the control unit 80 sets “0” for NDL2_H_S2, NDL3_H_S2, and NDL4_H_S2.

When “5” is inputted for VU, the control unit 80 sets “5” for NDL1_VU_S2, NDL2_VU_S2, NDL3_VU_S2 and NDL4_VU_S2. Further, when “5” is inputted for VD, the control unit 80 sets “5” for NDL1_VD_S2, NDL2_VD_S2, NDL3_VD_S2 and NDL4_VD_S2.

When “100” is inputted for NDL1_T, NDL2_T, NDL3_T, and NDL4_T, the control unit 80 sets “100” for NDL1_T_S2, NDL2_T_S2, NDL3_T_S2, and NDL4_T_S2.

As described above, when the pushup parameters are set, the blocks BL1 to BL4 are pushed up to a height of 300 μm in the first step as depicted within the dashed line BLK in FIG. 18. In the second step, the blocks BL1, BL2, and BL3 descend in the order named.

It should be noted that, as depicted within the dashed line BLK in FIG. 18, the control unit 80 may cause the setting screen 103 to display the height of the blocks BL1 to BL4 in the first to fourth steps in accordance with the set parameters.

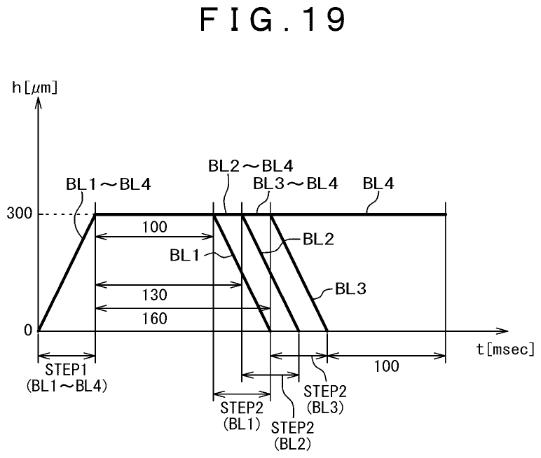

Operations of the individual blocks, which are set in the setting screen 103 depicted in FIG. 18, will now be described with reference to FIG. 19. FIG. 19 is a diagram illustrating the timing of block operations performed in a pushup sequence based on the settings in the setting screen depicted in FIG. 18.

### First Step (STEP 1):

The blocks BL1 to BL4 ascend to a height of 300 μm at a velocity of 5 mm/sec, and then stop. After a lapse of 100 msec since the stoppage of the block BL1 (the end of the first step), the block BL1 proceeds to the second step. After a lapse of 130 msec since the stoppage of the block BL2 (the end of the first step), the block BL2 proceeds to the second step. After a lapse of 160 msec since the stoppage of the block BL3 (the end of the first step), the block BL3 proceeds to the second step. After a lapse of 160 msec since the stoppage of the block BL4 (the end of the first step), the block BL4 proceeds to the second step.

### Second Step (STEP 2):

The block BL1 descends to a height of 0 μm at a velocity of 5 mm/sec, and then stops. The block BL2 descends to a height of 0 μm at a velocity of 5 mm/sec, and then stops. The block BL3 descends to a height of 0 μm at a velocity of 5 mm/sec, and then stops. The block BL4 maintains a height of 300 μm.

A time point at which the second step ends (the latest of the blocks BL1 to BL3) serves as the starting point of the first setting (second step) for NDL1_T to NDL4_T. After a lapse of 100 msec since the end of the second step, the collet 22 begins to ascend. The present embodiment provides at least one of the following advantageous effects.
(a) A plurality of pushup parameters can be set by inputting one of setting items displayed on the setting screen. This makes it possible to reduce input effort.
(b) The parameters of all blocks or all steps can be set by a single input for one block or one step. This makes it possible to reduce input effort and errors.
(c) Input items can be limited by providing the setting screen for a specific pushup sequence, it is possible to limit the input items.
(d) Inputted settings can easily be expanded to the pushup parameters due to (c) above.
(e) Input effort can be reduced due to (c) above.

The present disclosure made by the present inventors has been specifically described above based on an embodiment. However, it is obvious that the present disclosure is not limited to the foregoing embodiment and can be variously modified.

The forgoing embodiment has been described with reference to an example in which the number of drive shafts is four. Alternatively, however, the number of drive shafts may be less than or more than four.

The forgoing embodiment has been described with reference to an example in which the pushup unit is pushed up by a block. Alternatively, however, the pushup unit may be pushed up by a needle.

The foregoing embodiment has been described with reference to an example in which the die attach film is used. However, an alternative is to provide a preform unit for applying an adhesive to the substrate without using the die attach film.

The die bonder described in conjunction with the foregoing embodiment is configured such that the pickup head picks up the dies from the wafer supply unit, places the dies on the intermediate stage, and allows a bonding head to bond the dies placed on the intermediate stage to the substrate. However, the present disclosure is not limited to the above-mentioned configuration. The present disclosure can also be applied to a die bonding device that picks up dies from the wafer supply unit.

For example, the present disclosure is also applicable to a die bonder that has neither an intermediate stage nor a pickup head and allows the bonding head to bond the dies in the wafer supply unit to the substrate.

Further, the present disclosure is also applicable to a flip chip bonder that does not have an intermediate stage, picks up the dies from the wafer supply unit, rotates a die pickup head upward to deliver the dies to the bonding head, and allows the bonding head to bond the dies to the substrate.

In the foregoing embodiment, a die bonder has been described as an example. However, the present disclosure is also applicable to a semiconductor manufacturing apparatus that places a picked-up dies on a tray.

### Reference Signs List

What is claimed is:

1. A semiconductor manufacturing apparatus comprising:
a pushup unit having a plurality of blocks that are each able to independently move up and down;
a display device that configures a pushup sequence for the plurality of blocks with a plurality of steps, and displays a setting screen that allows the height of the plurality of blocks to be inputted for each step; and
a control unit that is configured to be able to set a plurality of pushup parameters upon input of one of setting items displayed on the setting screen and control the operations of the plurality of blocks in accordance with the setting plurality of pushup parameters.

2. The semiconductor manufacturing apparatus according to claim 1,
wherein the display device is configured to display a setting screen for inputting a first pushup sequence and a setting screen for inputting a second pushup sequence;
wherein the first pushup sequence is a sequence for a multi-stage operation that is performed to push up the all the blocks to a predetermined height and sequentially push up the inner one of the blocks; and
wherein the second pushup sequence is a sequence for a reverse multi-stage operation that is performed to push up all the blocks to a predetermined height and sequentially lower the outer one of the blocks.

3. The semiconductor manufacturing apparatus according to claim 2,
wherein the setting screen for inputting the first pushup sequence allows the height of the outermost block to be inputted in a first-step input area, and allows the height of an inner block adjacent to the outermost block to be inputted in a second-step input area.

4. The semiconductor manufacturing apparatus according to claim 2,
wherein the setting screen for inputting the second pushup sequence allows the height of the innermost block to be inputted in the first-step input area, and allows the height of the outermost block to be inputted in the second-step input area.

5. The semiconductor manufacturing apparatus according to claim 2,
wherein the display device is configured to display the setting screen that allows the first and second pushup sequences to be inputted.

6. The semiconductor manufacturing apparatus according to claim 1,
wherein the control unit is configured to be able to set the pushup parameters of the height of all the blocks for each step in accordance with the height of one of the blocks inputted for each step.

7. The semiconductor manufacturing apparatus according to claim 2,
wherein the control unit is configured to be able to set the pushup parameters of the height of all the blocks for each step in accordance with the height of one of the blocks inputted for each step.

8. The semiconductor manufacturing apparatus according to claim 3,
wherein the control unit is configured to be able to set the pushup parameters of the height of all the blocks for each step in accordance with the height of one of the blocks inputted for each step.

9. The semiconductor manufacturing apparatus according to claim 4,
wherein the control unit is configured to be able to set the pushup parameters of the height of all the blocks for each step in accordance with the height of one of the blocks inputted for each step.

10. The semiconductor manufacturing apparatus according to claim 1,
wherein the setting screen is configured to allow the pushup velocity of the plurality of blocks to be inputted for each step.

11. The semiconductor manufacturing apparatus according to claim 2,
wherein the setting screen is configured to allow the pushup velocity of the plurality of blocks to be inputted for each step.

12. The semiconductor manufacturing apparatus according to claim 3,
wherein the setting screen is configured to allow the pushup velocity of the plurality of blocks to be inputted for each step.

13. The semiconductor manufacturing apparatus according to claim 4,
wherein the setting screen is configured to allow the pushup velocity of the plurality of blocks to be inputted for each step.

14. The semiconductor manufacturing apparatus according to claim 5,
wherein the setting screen is configured to allow the pushup velocity of the plurality of blocks to be inputted for each step.

15. The semiconductor manufacturing apparatus according to claim 1,
wherein the setting screen is configured to allow an input to be made for each timer step, the timer step being the time interval between the end of ascent or descent of the plurality of blocks and the start of ascent or descent of the plurality of blocks in the next step.

16. The semiconductor manufacturing apparatus according to claim 2,
wherein the setting screen is configured to allow an input to be made for each timer step, the timer step being the time interval between the end of ascent or descent of the plurality of blocks and the start of ascent or descent of the plurality of blocks in the next step.

17. The semiconductor manufacturing apparatus according to claim 3,
wherein the setting screen is configured to allow an input to be made for each timer step, the timer step being the time interval between the end of ascent or descent of the plurality of blocks and the start of ascent or descent of the plurality of blocks in the next step.

18. The semiconductor manufacturing apparatus according to claim 4,
wherein the setting screen is configured to allow an input to be made for each timer step, the timer step being the time interval between the end of ascent or descent of the plurality of blocks and the start of ascent or descent of the plurality of blocks in the next step.

19. The semiconductor manufacturing apparatus according to claim 5,
wherein the setting screen is configured to allow an input to be made for each timer step, the timer step being the time interval between the end of ascent or descent of the plurality of blocks and the start of ascent or descent of the plurality of blocks in the next step.

20. The semiconductor manufacturing apparatus according to claim 4,
wherein the setting screen is configured to further allow the height of the outermost block to be inputted in the first-step input area.

21. A pushup method adopted by a semiconductor manufacturing apparatus including a pushup unit having a plurality of blocks that are each able to independently move up and down, and a display device that configures a pushup sequence for the plurality of blocks with a plurality of steps, and displays a setting screen that allows the height of the plurality of blocks to be inputted for each step, the pushup method comprising the steps of:
setting a plurality of pushup parameters based on the input of one of setting items displayed on the setting screen; and
controlling the operations of the plurality of blocks in accordance with the setting plurality of pushup parameters.

22. A method for manufacturing semiconductor device comprising the steps of:
using the pushup method according to claim 10 to peel off a die from a wafer held by a wafer ring and pick up the die; and
bonding the picked-up die to a substrate.
